(19) United States
(12) Patent Application Publication
(10) Pub. No.: US 2009/0108891 A1
(43) Pub. Date: Apr. 30, 2009

(54) BANDWIDTH CONTROL IN A MOSTLY-DIGITAL PLL/FLL

(75) Inventors: Wendell Sander, Los Gatos, CA (US); Brian Sander, San Jose, CA (US)

Correspondence Address: PATENT LAW PROFESSIONALS, P.O. BOX 612407, SAN JOSE, CA, 95161, US

(73) Assignee: Matsushita Electric Industrial Co., Ltd.

(21) Appl. No.: 12/249,170

(22) Filed: Oct. 10, 2008

Related U.S. Application Data
(60) Provisional application No. 60/983,136, filed on Oct. 26, 2007.

(51) Int. Cl. H03L 7/06

(52) U.S. Cl. 327/156

(57) ABSTRACT

Methods and apparatus for controlling a controlled oscillator using a phase-locked loop (PLL) or frequency-locked loop (FLL) having a digital loop filter with programmable filter parameters. An exemplary PLL (or FLL) includes a digital loop filter having one or more of the programmable filter parameters, which are changed by increments during operation in order to minimize disturbances (e.g., settling transients) as the loop bandwidth of the PLL is varied from a narrow loop bandwidth to a wide loop bandwidth, or vice versa. By changing the loop filter parameters in increments the loop bandwidth can be varied with substantially no perturbation. The end result is a much faster frequency switching time, improved settling dynamics, and predictable and stable loop operating performance. According to another aspect of the invention, one or more of the programmable filter parameters are changed in order to oppose a change in tuning sensitivity of the controlled oscillator (e.g., in order to maintain a constant loop bandwidth). By holding the loop bandwidth constant, switching time is maintained substantially constant under all conditions. This allows design and production margins to be reduced in a frequency agile system, and also relaxes the tuning sensitivity linearity requirements of the controlled oscillator.

### CROSS-REFERENCE TO RELATED APPLICATIONS

This patent application claims the benefit of U.S. Provisional Patent Application No. 60/983,136, filed on Oct. 26, 2007, the disclosure of which is hereby incorporated by reference.

### FIELD OF THE INVENTION

The present invention relates to phase-locked loops (PLLs) and frequency-locked loops (FLLs), particularly loops of mostly-digital construction.

### BACKGROUND OF THE INVENTION

Direct digital frequency synthesis (DDFS) consists of generating a digital representation of a desired signal, using logic circuitry and/or a digital computer, and then converting the digital representation to an analog waveform using a digital-to-analog converter (DAC). Such systems can be compact, low power, and can provide very fine frequency resolution with virtually instantaneous switching of frequencies.

One of the challenges of DDFS has been to generate a clean, precisely-modulated waveform. Because of limited time resolution and edge misalignment, spurious output signal transitions (i.e., “spurs”) occur.

Precision modulation is also a problem in conventional analog frequency synthesizers using a phase-locked loop (PLL). The problem occurs that the PLL treats signal modulation as drift and attempts to cancel the modulation. Various circuit arrangements have been devised in an attempt to overcome this problem. Such circuit arrangements do not enjoy the benefits of DDFS.

U.S. Pat. No. 6,094,101 to Sander describes improved methods of generating clean, precisely-modulated waveforms, at least partly using digital techniques. As described therein, a “difference engine” is provided that produces a digital signal representing the frequency error between a numeric frequency and an analog frequency. The frequency error may be digitally integrated to produce a digital signal representing the phase error. The difference engine may be incorporated into a phase-locked loop or a frequency-locked loop (PLL/FLL), where the analog frequency is that of an output signal of a VCO of the PLL/FLL. Direct modulation of the PLL/FLL output signal may be performed numerically. By further providing an auxiliary modulation path and performing calibration between the direction modulation path and the auxiliary modulation path, modulation characteristics may be separated from loop bandwidth constraints. In particular, the loop bandwidth of the PLL/FLL may be made so low as to reduce spurs (usually associated with DDFS techniques) to an arbitrarily low level. A loop filter of the PLL/FLL may be realized in digital form.

Referring to FIG. 1, in accordance with the teachings of Sander, a mostly-digital PLL/FLL includes a “slow path” and an auxiliary “fast path” used to control and directly modulate the output signal of a VCO. Considering first the slow path, a numeric modulation input is applied to a difference engine 101 for direct modulation. An output signal of the VCO 103 is also applied to the difference engine 101, which produces a digital phase error signal and a digital frequency error signal. To achieve a low loop bandwidth (e.g., for spur reduction), a digital loop filter 105 is used followed by a DAC 107, shown as a Sigma-Delta DAC (EΔ-DAC). The error signals produced by the difference engine 101 are filtered by the digital loop filter 105, to produce a stream of digital output bits. These bits are converted to an analog control voltage by the EΔ-DAC 107 and applied through a filter R2C2 to a tuning input of the VCO 103.

In the fast path, the numeric modulation input is applied through a multiplier 109 to a second EΔ-DAC 111. An output voltage produced by the second EΔ-DAC 111 is applied through an RC circuit R1C1 to the VCO 103. The PLL/FLL of FIG. 1 has the property that if the direct modulation (“slow path”) gain is exactly matched in the auxiliary modulation (“fast path”) gain, then the output frequency of the PLL/FLL can be changed without changing the closed-loop modulation voltage. This property in turn implies that modulation is not subject to loop bandwidth constraints. The loop bandwidth may be set to an arbitrarily low level, for example, allowing DDFS spurs to be filtered down to a desired level.

Note that modulation is injected at two different points in the circuit, through the main loop and through the separate modulation path. When the modulation is changed, it is changed at these two different points at the same time. This may be achieved by “dosing” part of the modulation signal from the separate modulation path to the main loop. To accomplish this dosing, the modulation input signal of the separate modulation path is scaled by a factor ‘F’ and input to the summing DAC of the main loop through a path 113. According to one implementation, F=C1/(C1+C2).

The multiplier 109 is provided to allow the direct modulation gain to be matched in the auxiliary modulation gain. The multiplier 109 applies a scale factor ‘M’ to the numeric modulation input, and the resulting scaled signal is applied to the EΔ-DAC, which functions now as a summing DAC.

Referring to FIG. 2, the scale factor ‘M’ may be determined by measuring a maximum frequency step using a digital filter 201. To do so, the minimum numeric frequency is first applied to the difference engine 101. Then the maximum numeric frequency is applied. The frequency error signal produced by the difference engine 101 is filtered using the digital filter 201, which may comprise a finite impulse response filter, for example. The digital filter 201 measures the maximum frequency step. The appropriate scale factor ‘M’ may be determined by dividing the observed maximum frequency step by the desired maximum frequency step. Preferably, calculation of the scale factor ‘M’ is iterated multiple times. For each successive iteration the value obtained for the scale factor will more closely approximate the scale factor required for exact matching. Calibration may be performed at power-on and may optionally be performed thereafter at intervals or as required.

Despite the foregoing improvements, there nevertheless remains a need for further improved PLL/FLLs and control techniques for generating clean, precisely-modulated waveforms.

### BRIEF SUMMARY OF THE INVENTION

Methods and apparatus for controlling a controlled oscillator using a phase-locked loop (PLL) or frequency-locked loop (FLL) having a digital loop filter with programmable filter parameters are disclosed. An exemplary phased lock loop includes a controlled oscillator, a converter circuit, a numerically controlled synthesizer circuit, a digital loop filter having at least one programmable filter parameter, and a digital-to-analog converter (DAC). The controlled oscillator has a tuning port configured to receive an error signal generated by the PLL. The error signal is generated based on a difference signal between a digital signal generated by the converter circuit and a digital reference signal. The digital signal generated by the converter circuit has a pulse density representing the frequency of an output signal generated by the controlled oscillator. The digital reference signal has a pulse density representing a desired frequency of the controlled oscillator output signal. The digital loop filter filters the error signal, and the DAC converts the filtered error signal to an analog error signal, which is applied to the tuning port of the controlled oscillator.

According to one aspect of the invention, one or more of the programmable filter parameters of the digital loop filter are changed by increments during operation, in order to minimize disturbances (e.g., settling transients) as the loop bandwidth of the PLL is varied from a narrow loop bandwidth to a wide loop bandwidth, or vice versa. By changing the loop filter parameters gradually, i.e., in increments, the loop bandwidth can be varied with substantially no perturbation. The end result is a much faster frequency switching time, improved settling dynamics, and predictable and stable loop operating performance.

According to another aspect of the invention, one or more of the programmable filter parameters are changed in order to oppose a change in tuning sensitivity of the controlled oscillator (e.g., in order to maintain a constant loop bandwidth). A benefit of this aspect of the invention is that by holding the loop bandwidth constant, switching time is maintained substantially constant under all conditions. This is a very desirable design condition, since it reduces design and production margins in a frequency agile system. It also relaxes the tuning sensitivity linearity requirements of the controlled oscillator.

Further aspects of the invention are described and claimed below, and a further understanding of the nature and advantages of the invention may be realized by reference to the remaining portions of the specification and the attached drawings.

### BRIEF DESCRIPTION OF THE DRAWINGS

FIG. 1 is a block diagram of a known PLL/FLL;

FIG. 2 is a diagram illustrating a known multiply-calibration operation used in connection with the PLL/FLL of FIG. 1;

FIG. 3 is a block diagram of a PLL/FLL, according to an embodiment of the present invention;

FIG. 4 is a diagram illustrating a transfer function of the digital loop filter in FIG. 3;

FIG. 5 is a block diagram of a PLL/FLL, according to an embodiment of the present invention;

FIG. 6 is a block diagram of a PLL/FLL, according to an embodiment of the present invention;

FIG. 7 is a block diagram of a PLL/FLL, according to an embodiment of the present invention;

FIG. 8 is a block diagram of a PLL/FLL, according to an embodiment of the present invention;

FIG. 9 is a timing diagram illustrating operation of the PLL/FLL of FIG. 8;

FIG. 10 is a generalized block diagram showing a feedback control structure; and

FIG. 11 is s a block diagram showing an advantageous modification of the feedback control structure of FIG. 10.

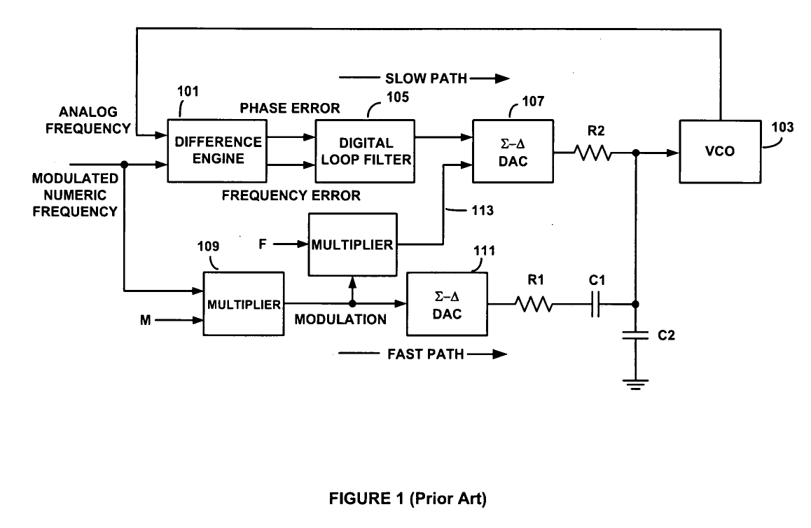

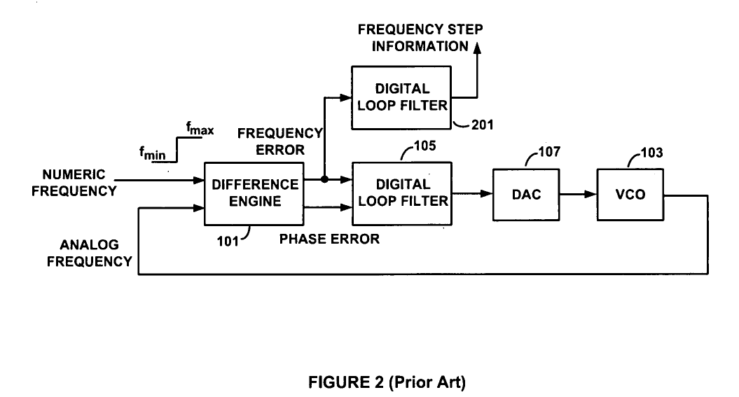

### DETAILED DESCRIPTION

Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. The same reference indicators will be used throughout the drawings and the following detailed description to refer to the same or like parts.

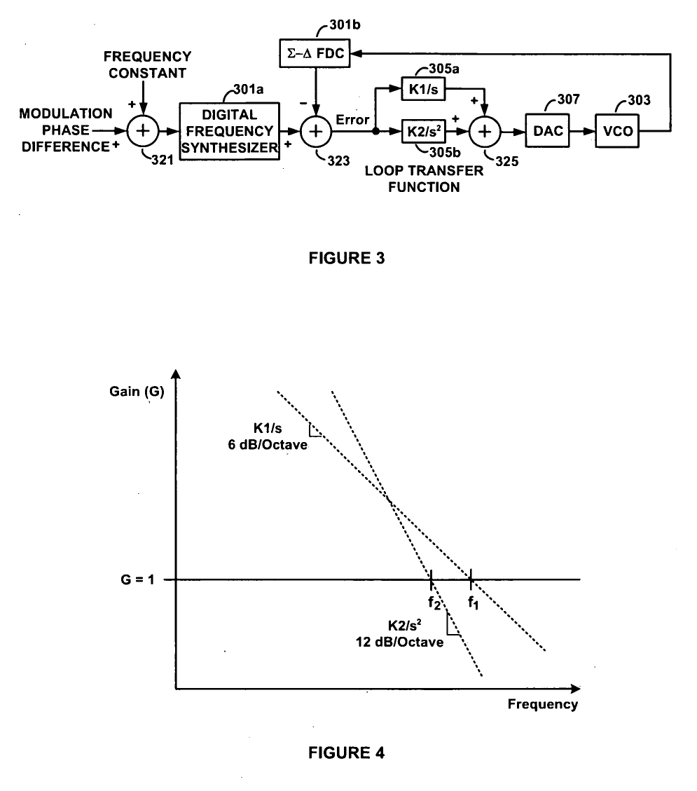

Referring now to FIG. 3, there is shown a block diagram of a PLL/FLL in accordance with one aspect of the present invention. A frequency constant is applied to an adder 321 together with a modulation phase difference signal. A resulting sum is applied to a digital frequency synthesizer (DFS) 301a. The DFS 301a outputs a stream of bits representing a desired frequency of a VCO 303, an output signal of which is input to a EΔ frequency-to-digital converter (EΔ-FDC) 301b. The EΔ-FDC 301b may be of a construction as described in the foregoing U.S. Pat. No. 6,094,101, which is hereby incorporated by reference.

The frequency constant may represent the center frequency of the VCO 303 for a particular communications channel. The modulation phase difference is a sample-time by sample-time change in the desired phase of the modulated signal. The modulation phase difference is phase accurate in the sense that if it were accumulated it would represent actual phase; as a phase difference, it is actually a frequency. In precise terms, the present loop is therefore actually a frequency-locked loop (FLL), although the phase-accurate properties of the loop are more typical of a phase-locked loop (PLL).

An adder 323 forms a difference between the respective output signals of the DFS 301a and the EΔ-FDC 301b, to form an error signal (also a stream of bits). The EΔ-FDC 301b provides a conversion output that is decimated down to the digital loop clock rate. The DFS 301a takes the desired “frequency” and generates a digital stream much like the digital portion of a EΔ-ADC with an output resolution to match the EΔ-FDC decimator at the loop clock frequency. Thus if the VCO 303 is at the desired frequency, then the EΔ-FDC 301b and the DFS 301a will be outputting the same average values, and if the VCO 303 is not at the desired frequency, then there will be an error from the adder 323. The error signal is applied to a digital loop filter.

In the illustrated embodiment, the digital loop filter may be represented in the form of two transfer functions. A first block 305a realizes a first-order transfer function of K1/s. A second block 305b realizes a second-order transfer function of K2/s². FIG. 4 is a diagram illustrating a transfer function of the digital loop filter in FIG. 3. Output signals of the first and second blocks 305a and 305b are summed by an adder 325. An output signal of the adder 325 is applied to a DAC 307, which may be a EΔ-DAC. An output signal of the DAC 307 is used to drive a tuning port of the VCO 303.

The main loop of the PLL/FLL in FIG. 3 may be viewed much like a motor control loop, where the VCO 303 is analogous to a motor whose output revolutions per minute is controlled by the loop. The second-order loop transfer function of the second block 305b is appropriate for this type of digital loop. In the loop structure of FIG. 3 as described, however, the DAC 307 is directly driving the VCO 303. In a typical application, the tuning sensitivity, Kv, of the VCO 303 can be 150 MHz/v with two volts of tuning range, while the modulation deviation can be as small as 15 kHz. This means that to have a modulation accuracy of 1%, the DAC 307 must have a one microvolt resolution, requiring a 21-bit DAC.

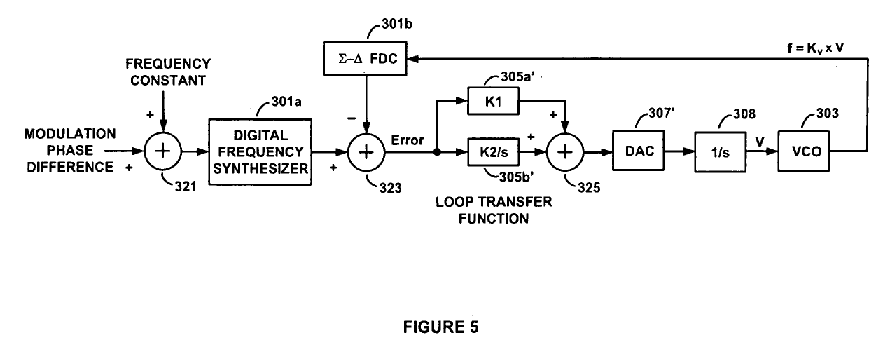

To avoid the stringent accuracy, resolution and noise requirements of such a DAC, the transfer function of the second block 305b may be split into two blocks arranged in series, one block 305b′ having a transfer function of K2/s and another block 308 having a transfer function of 1/s, which represents integration, as illustrated in FIG. 5. This integration operation may be performed by placing an analog integrator 308 after the DAC 307′. The DAC 307′ then becomes readily realizable, and a first-order EΔ-DAC may be used.

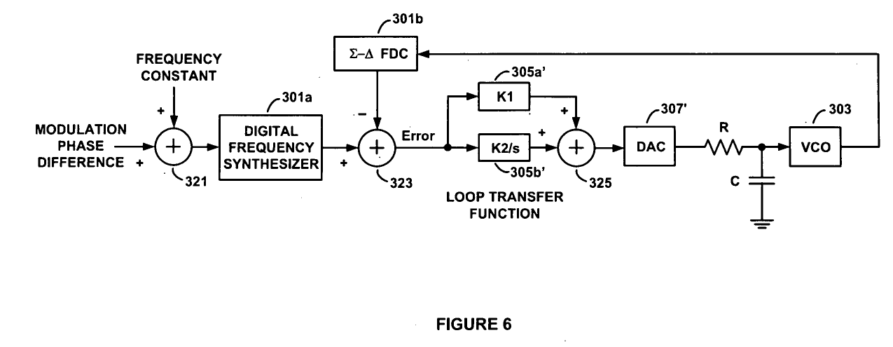

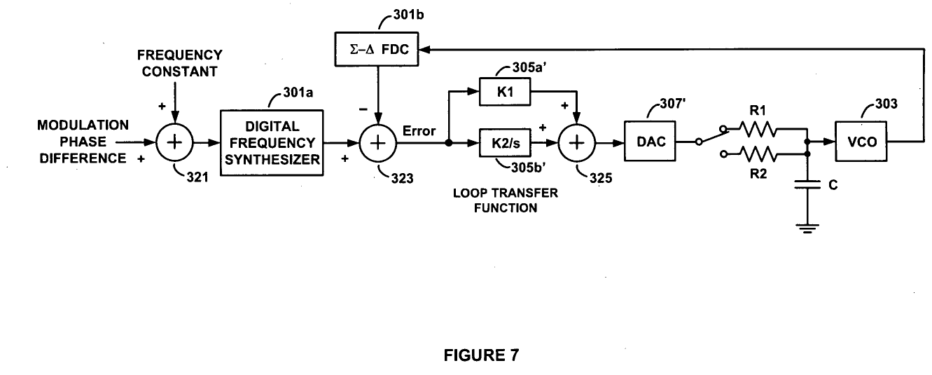

The analog integrator in the PLL/FLL of FIG. 5 may be realized in the form of a series resistor R and a shunt capacitor C, as illustrated in FIG. 6. It is advantageous to be able to change the value of the resistor R between a relatively low value (resulting in a high loop bandwidth suitable for acquisition mode) and a relatively high value (resulting in a low loop bandwidth suitable for tracking mode). In an alternative embodiment shown in FIG. 7, instead of using a single resistor R (as in FIG. 6), a choice of two resistors, R1 and R2, is provided, and a switch is used to switch between the two resistors.

The forward path in FIG. 7 corresponds in general to the “slow path” of the PLL/FLL of U.S. Pat. No. 6,094,101. By adding a fast path to the loop of FIG. 3, the output frequency of the PLL/FLL can be changed without changing the closed-loop modulation voltage. As a result, modulation is not subject to loop bandwidth constraints, and the loop bandwidth may be set to an arbitrarily low level, for example, allowing spurs to be filtered down to a desired level.

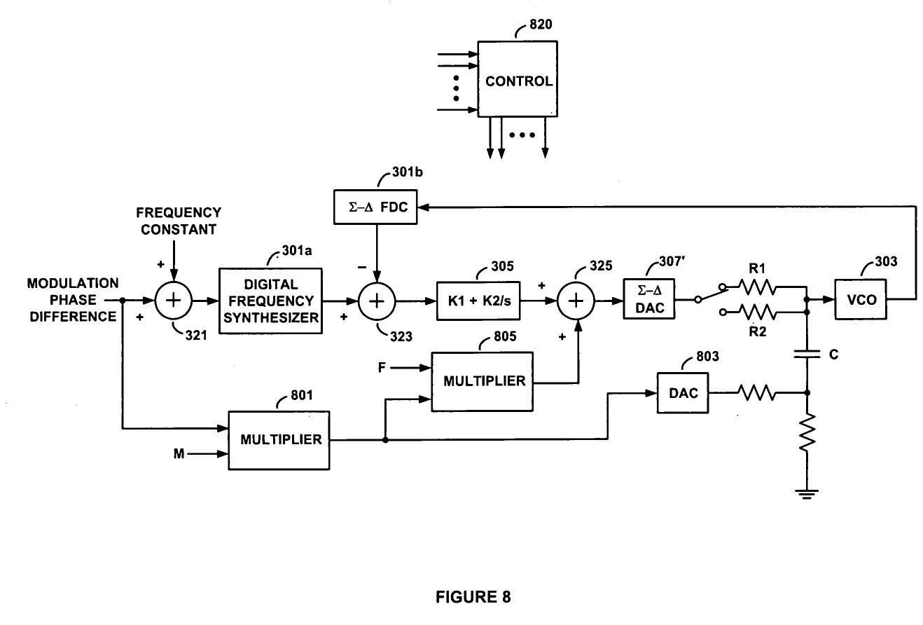

FIG. 8 illustrates the addition of such a fast path, as is described in W. B. Sander, S. V. Schell and B. L. Sander, “Polar Modulator for Multi-Mode Cell Phones,” IEEE 2003 Custom Integrated Circuits Conference, 21-24 Sep. 2003, pp. 439-445, which is hereby incorporated by reference. The modulation phase difference is multiplied by a first factor ‘M’ using a first multiplier 801, an output of which is applied to a DAC 803. A resulting analog voltage is applied through a resistive divider to a plate of the capacitor C opposite the plate producing the VCO tuning voltage. Further, an output signal of the multiplier 801 is multiplied by a second factor ‘F’ using a second multiplier 805. A resulting quantity is added to the output signal of the digital loop filter 305. In one embodiment, the first factor ‘M’ is determined using the results of a multiply calibration (“multcal”) operation such as that described in U.S. Pat. No. 6,094,101, so as to obtain a loop gain of unity at high frequencies. The factor ‘F’ is frequency dependent and is used to maintain unity gain across the frequency range.

In an ideal system, with the first and second factors ‘M’ and ‘F’ set properly, the error signal would be zero and all of the modulation would come from the fast path. The primary purposes of the slow path are to: (i) keep the carrier frequency accurate, and (ii) ensure that the overall system keeps precise track of input phase. A phase-accurate digital frequency modulator is thereby achieved.

In some applications or operating circumstances it may be desirable to adjust the loop bandwidth of the PLL/FLL, while in other applications or operating conditions it is desirable to maintain as constant a loop bandwidth as possible. The systems and methods of the present invention fulfill these needs by providing loop transfer function parameters K1 and K2 having values that are programmable and modifiable during operation. According to one aspect of the invention various values for each loop transfer function parameter are stored in a memory or look-up table (LUT), and a controller 820 (e.g., implemented using a digital signal processor (DSP)) is configured to access different values of the loop transfer function parameters during operation of the PLL or FLL.

In applications or operating circumstances where it is desired to adjust the loop bandwidth of the PLL/FLL, according to an embodiment of the invention the values of the loop transfer function parameters K1 and K2 are modified incrementally and on the fly as the PLL/FLL is operated, in order to reduce settling transients resulting from changes in the loop bandwidth of the PLL/FLL, e.g., from a wide loop bandwidth to a comparatively more narrow bandwidth. The appropriate loop transfer function parameter values needed are determined from predicted, simulated or measured behavior of the PLL/FLL. For example, the appropriate loop transfer function parameter values can be determined based on perturbation tests performed on the PLL/FLL, as will be appreciated and understood by those of ordinary skill in the art. According to one embodiment of the invention, once the determined loop transfer function parameter values have been determined, they are stored in a LUT or other system register for quick access during operation of the PLL/FLL. By modifying the values of the loop transfer function parameters K1 and K2 slowly, e.g., as the PLL/FLL is reconfigured for operation between the slow and fast paths, settling transients caused by changes in loop bandwidth are made to settle in a much shorter time than possible with no change to the parameters. The end result is a much faster frequency switching time for the synthesizer, with excellent settling dynamics and predictable and stable performance.

In applications or operating circumstances where it is desired to maintain as constant a loop bandwidth as possible over a tuning range of the PLL/FLL, according to another embodiment of the invention the values of the loop transfer function parameters K1 and K2 are varied during operation to maintain a desired constant loop bandwidth. Maintaining a constant loop bandwidth is a desirable condition in many operating conditions since it minimizes design and production margins in a frequency agile system. It also allows for loop component (such as the VCO, for example) to have relaxed tuning sensitivity linearity requirements, thereby reducing costs and increasing sourcing and design options. The appropriate values of the loop transfer function parameter values needed to maintain the desired constant loop bandwidth are determined based on predicted, simulated or measured behavior of the PLL/FLL. For example, the appropriate parameter values can be determined based on impulse response or step response tests performed on the PLL/FLL, as will be appreciated by those of ordinary skill in the art. According to one embodiment of the invention, once the appropriate loop transfer function parameter values have been determined, they are stored in a LUT or other system register for quick access during operation of the PLL/FLL. The feed-forward technique of the PLL/FLL in FIG. 8 may require the tuning sensitivity Kv of the VCO 303 to be measured. According to one aspect of the invention, the tuning sensitivity Kv is measured during a multiply calibration (“multcal”) operation. Changes in tuning sensitivity of the VCO due to component aging and temperature shifts are thereby compensated for, and the requirements of the VCO in terms of linearity and compensation may therefore be reduced.

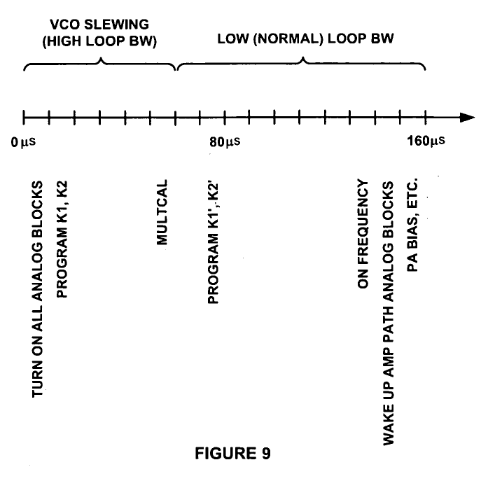

FIG. 9 shows a timeline illustrating an example of the manipulation of K1 and K2 values during burst preparation, in the case of the General Packet Radio Service (GPRS) standard. During an initial period (roughly 10 microseconds) analog blocks turned off previously for power savings are again turned on. The resistor R1 is selected and the parameters K1 and K2 are programmed for high loop bandwidth. During an ensuing period (roughly 50 microseconds) the VCO 303 slews to a target frequency with a residual error of up to 1 kHz. The resistor R2 is then selected for normal (low) loop bandwidth. A multcal operation is then performed in similar manner as previously described, during which the VCO tuning sensitivity Kv is measured. The multcal operation is performed “open loop” in the sense that, although the error signal still gets processed by the slow-path filters, the slow path output signal is artificially held at a constant value. After the multcal operation has been completed, closed loop operation is resumed. New values K1′ and K2′ are then programmed as a function of frequency and Kv as measured during the multcal operation. Within a period of roughly 80 microseconds, the frequency error is reduced to less than 10 Hz. The GPRS specification allows 160 microseconds for burst preparation. Twenty or more microseconds therefore remains for such activities as, in the case of a polar modulation system, turning on analog blocks of an amplitude modulation path, setting power amplifier bias, etc.

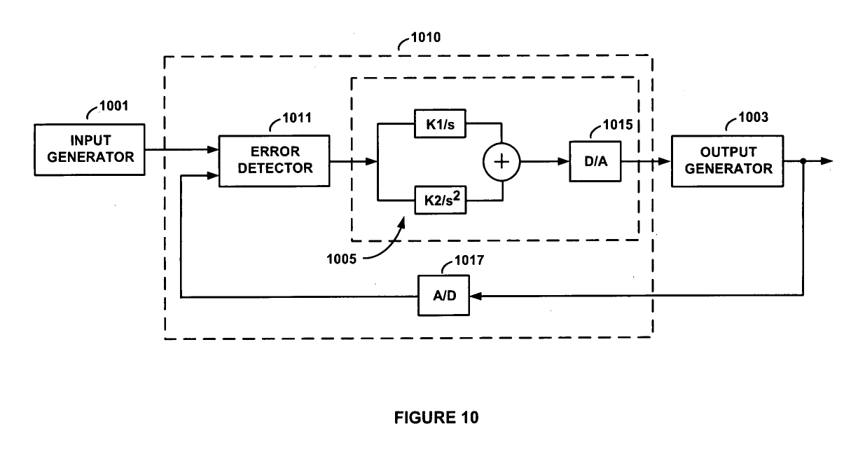

The foregoing techniques for overcoming the stringent accuracy, resolution and noise requirements that might otherwise apply to a digital to analog (D/A) converter may be applied generally to feedback control systems. Referring to FIG. 10, there is shown a generalized feedback control system having an input generator 1001, an output generator 1003, and a feedback control circuit 1010. A forward loop of the feedback control circuit includes an error detector 1011, a filter structure 1005, and a D/A converter 1015. A reverse loop includes an analog to digital (A/D) converter 1017, which converts an analog output signal of the output generator 1003 to digital form and applies the resulting digital signal to the error detector 1011. The error detector 1011 receives a signal indicative of a desired output signal from the input generator, and produces an error signal based on a difference between the actual output signal and the desired output signal. The error signal is filtered in the filter structure 1005, and the resulting filtered error signal is applied to the output generator 1003 to cause corrective action.

In the illustrated system, the filter structure 1005 includes two parallel branches, one of the branches including a K1/s operator and the other branch including a K2/s² operator. The operators receive the error signal and perform their respective operations to produce signals that are summed together and applied to the D/A converter 1015. The illustrated filter structure has been shown to be advantageous from the standpoint of loop stability. However, in the system as shown, extreme requirements may be placed on the D/A converter 1015 that are difficult to realize.

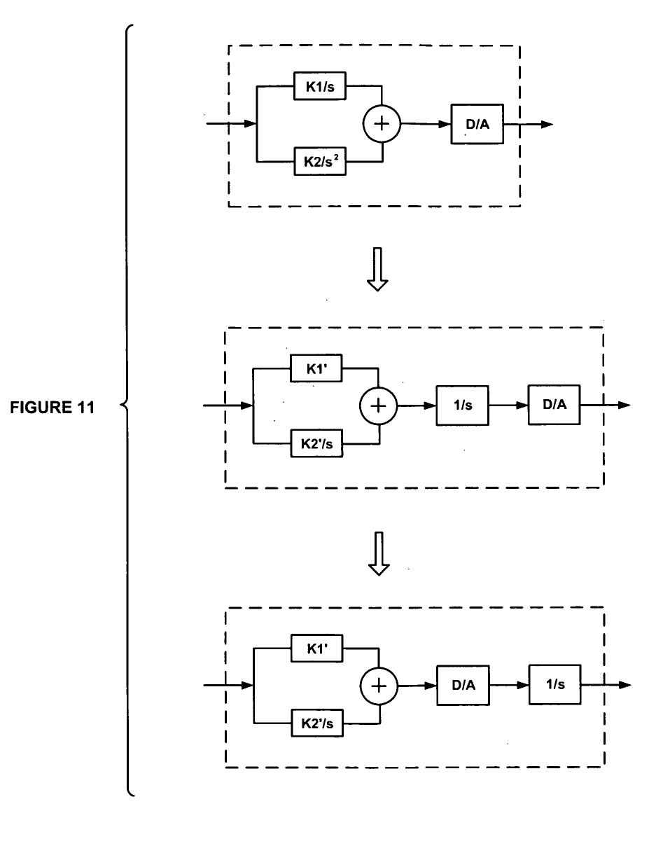

In accordance with one aspect of the invention, these requirements may be relaxed by employing a series of transformations to arrive at a structure that accomplishes the equivalent control function, as illustrated in FIG. 11. In a first step of the transformation, a 1/s operator is removed from the operators of the two parallel branches and placed following the summer. That is, the K1/s operator is replaced by a K1′ operator, and the K2/s² operator is replaced by a K2′/s operator, (where the constants K1 and K1′ and K2 and K2′, respectively, may or may not be equal). A 1/s operator is then added following the summer, maintaining equivalence. In a second step of the transformation, the 1/s operator and the D/A converter are interchanged, such that the D/A converter directly follows the summer and is followed in turn by the 1/s operator, which is equivalent to an analog integration. Because the output of the D/A converter is integrated in an analog integrator, the accuracy, resolution and noise requirements of the D/A converter may be substantially relaxed.

Although various exemplary embodiments of the invention have been described in detail, it should be understood that various changes, substitutions and alternations can be made without departing from the spirit and scope of the inventions as defined by the appended claims.

What is claimed is:

1. A phase-locked loop (PLL) or frequency-locked loop (FLL), comprising:
a controlled oscillator having a rate of oscillation that varies in accordance with a tuning input signal, and exhibits a tuning sensitivity that varies as the rate of oscillation varies;
a converter circuit coupled to an output signal of said controlled oscillator configured to generate a first digital output signal having a pulse density representing a frequency of an actual output signal of the controlled oscillator;
a numerically-controlled synthesizer circuit, responsive to a digital input signal, configured to generate a second digital output signal having a pulse density representing a frequency of a desired output signal;
a differencer configured to generate an error signal based on a difference between the first and second digital output signals;
a digital loop filter having at least one programmable filter parameter and operable to output a filter output signal in response to the error signal;
a digital to analog converter having an input configured to receive the filter output signal and an output configured to provide a control signal to a control input of the controlled oscillator for controlling the rate of oscillation thereof; and
control circuitry configured to change a value of one or more parameters of said at least one programmable filter parameter in a manner that reduces a settling transient resulting from a change in a loop bandwidth of the PLL or FLL.

2. The phase-locked loop or frequency-locked loop of claim 1 wherein the control circuitry is configured to change the value of said one or more parameters of said at least one programmable filter parameter in increments as the loop bandwidth is varied.

3. The phase-locked loop or frequency-locked loop of claim 1 wherein the plurality of programmable filter parameters includes a first scale factor corresponding to a first-order transfer function and a second scale factor corresponding to a second-order transfer function.

4. The phase-locked loop or frequency-locked loop of claim 1 wherein said converter circuit comprises a sigma-delta modulator.

5. The phase-locked loop or frequency-locked loop of claim 4 wherein said sigma-delta modulator is first-order.

6. The phase-locked loop or frequency-locked loop of claim 5, further comprising an analog integrator coupled between said digital to analog converter and said controlled oscillator.

7. The phase-locked loop or frequency-locked loop of claim 1 wherein said control circuitry is further configured to change a value of said one or more parameters of said at least one programmable filter parameter to increase loop stability or quicken response time.

8. The phase-locked loop or frequency-locked loop of claim 1 wherein said control circuitry is further configured to change a value of said one or more parameters of said at least one programmable filter parameter in a manner that helps maintain a constant loop bandwidth during operation of the PLL or FLL.

9. A phase-locked loop or frequency-locked loop of claim 1 wherein the control circuitry is further configured to change a value of said one or more parameters of said at least one programmable filter parameter in a manner that opposes a change in a tuning sensitivity of said controlled oscillator.

10. A phase-locked loop (PLL) or frequency-locked loop (FLL), comprising:
a controlled oscillator having a rate of oscillation that varies in accordance with a tuning input signal, and exhibits a tuning sensitivity that varies as the rate of oscillation varies;
a converter circuit coupled to an output signal of said controlled oscillator configured to generate a first digital output signal having a pulse density representing a frequency of an actual output signal of the controlled oscillator;
a numerically-controlled synthesizer circuit, responsive to a digital input signal, configured to generate a second digital output signal having a pulse density representing a frequency of a desired output signal;
a differencer configured to generate an error signal based on a difference between the first and second digital output signals;
a digital loop filter having at least one programmable filter parameter and operable to output a filter output signal in response to the error signal;
a digital to analog converter having an input configured to receive the filter output signal and an output configured to provide a control signal to a control input of the controlled oscillator for controlling the rate of oscillation thereof; and
control circuitry configured to change a value of one or more parameters of said at least one programmable filter parameter in a manner that helps maintain a constant loop bandwidth during operation of the PLL or FLL.

11. A phase-locked loop or frequency-locked loop processing method, comprising:
providing a tuning input signal to a controlled oscillator having a rate of oscillation that varies in accordance with the tuning input signal and exhibiting a tuning sensitivity that varies as the rate of oscillation varies;
responsive to an output signal of said controlled oscillator, generating a first digital output signal having a pulse density representing a frequency of an actual output signal of the controlled oscillator;
responsive to a digital input signal, generating a second digital output signal having a pulse density representing a frequency of a desired output signal;
generating an error signal from a difference between said first and second digital output signals;
filtering said error signal in accordance with at least one programmable filter parameter and outputting a filter output signal;
converting the filter output signal to an analog signal that controls the rate of oscillation of said controlled oscillator; and
changing a value of one or more parameters of said at least one programmable filter parameter in a manner that shortens durations of settling transients during times when a loop bandwidth of the PLL or FLL varies.

12. The method of claim 11 wherein changing the value of one or more parameters of said at least one programmable filter parameter in a manner that shortens the durations of settling transients comprises changing the value of said one or more parameters in increments.

13. The method of claim 11, further comprising changing a value of said one or more parameters of said at least one programmable filter parameter to increase loop stability or quicken response time of the PLL or FLL.

14. The method of claim 11, further comprising measuring a change in the tuning sensitivity of said controlled oscillator.

15. The method of claim 14, further comprising using the measured change in tuning sensitivity of said controlled oscillator to change a value of one or more parameters of said at least one programmable filter parameter in a manner that opposes the change in tuning sensitivity.

16. A phase-locked loop or frequency-locked loop processing method, comprising:
providing a tuning input signal to a controlled oscillator having a rate of oscillation that varies in accordance with the tuning input signal and exhibiting a tuning sensitivity that varies as the rate of oscillation varies;
responsive to an output signal of said controlled oscillator, generating a first digital output signal having a pulse density representing a frequency of an actual output signal of the controlled oscillator;
responsive to a digital input signal, generating a second digital output signal having a pulse density representing a frequency of a desired output signal;
generating an error signal from a difference between said first and second digital output signals;
filtering said error signal in accordance with at least one programmable filter parameter and outputting a filter output signal;
converting the filter output signal to an analog signal that controls the rate of oscillation of said controlled oscillator; and
changing a value of one or more parameters of said at least one programmable filter parameter in a manner that helps maintain a constant loop bandwidth during operation of the PLL or FLL.

17. A combination filter/data converter for filtering a digital error signal to produce an analog control signal, comprising:
a first filter portion performing a first portion of a desired filter function to produce an intermediate digital signal;
a digital to analog converter responsive to the intermediate digital signal for producing a corresponding analog intermediate signal; and
a second filter portion for integrating the analog intermediate signal, thereby performing a second portion of the desired filter function.

18. The combination filter/data converter of claim 17 wherein the desired filter function includes a term that involves a first integral of the digital error signal and a term that involves a second integral of the digital error signal.

19. The combination filter/data converter of claim 17 wherein the second portion of the desired filter function comprises integration.
